(19) United States
(12) Patent Application Publication
(10) Pub. No.: US 2011/0283155 A1
(43) Pub. Date: Nov. 17, 2011

(54) APPARATUS AND METHOD FOR TRANSMITTING/RECEIVING DATA IN A COMMUNICATION SYSTEM

(75) Inventors: Il-Gu LEE, Seoul (KR); Jong-Ee Oh, Daejeon (KR); Sok-Kyu Lee, Daejeon (KR)

(73) Assignee: Electronics and Telecommunications Research Institute, Daejeon (KR)

(21) Appl. No.: 13/105,650

(22) Filed: May 11, 2011

(30) Foreign Application Priority Data
May 11, 2010 (KR) 10-2010-0043994

(51) Int. Cl. H03M 13/05; G06F 11/10

(52) U.S. Cl. 714/746; 714/807; 714/800; 714/E11.032

(57) ABSTRACT

A data transmission apparatus in a wireless communication system includes: a data field generation unit configured to generate a data field for transmitting data; a signal field generation unit configured to generate a signal field for transmitting information on the data field; and a transmission unit configured to transmit a data packet containing the data field and the signal field. The signal field includes a rate bit, a reservation bit, a length bit, a parity check bit, and a tail bit, and the data transmission apparatus transmits a check bit for checking whether the signal field is normal or not through two or more bits of the bits of the signal field.

### CROSS-REFERENCE TO RELATED APPLICATIONS

The present application claims priority of Korean Patent Application No. 10-2010-0043994, filed on May 11, 2010, which is incorporated herein by reference in its entirety.

### BACKGROUND OF THE INVENTION

1. Field of the Invention

Exemplary embodiments of the present invention relate to a communication system; and, more particularly, to a data transmission/reception apparatus and method for normally transmitting/receiving data by checking a signal field in a communication system.

2. Description of Related Art

In a current communication system, research has been actively conducted on a method for providing users with services having various quality of services (QoS) with a high transmission rate. In a wireless local area network (WLAN) system as an example of the communication system, research has been actively conducted on methods for stably transmitting large data at high speed through a limited resource. Particularly, in a communication system, research has been conducted on data transmission through a wireless channel. Recently, a variety of methods for normally transmitting/receiving large data by effectively using limited wireless channels have been proposed in the WLAN system.

Meanwhile, large data transmitted/received through a wireless channel in a communication system, for example, a data packet includes a data field containing data transmitted/received through the wireless channel and a signal field containing information on the data field. The communication system checks whether the signal field is normal or not and then normally transmits/receives the data contained in the data field according to whether the signal field is normal or not.

In a current communication system, however, the large data are contained in the data field of the data packet and then transmitted/received, in order to stably transmit/receive the large data at high speed through a limited resource. Accordingly, when the data field of the data packet is expanded to the maximum, there is a limit in expanding the signal field. Furthermore, the current signal field is insufficient to contain the information on the data field expanded to the maximum in the signal field. In particular, in order to normally transmit/receive the large data through a limited resource as described above, whether the signal field is normal or not should be necessarily checked. However, there is a limit in accurately checking whether the signal field is normal or not through a minimum bit allocated to check whether the signal field is normal or not, for example, one bit. As a result, there is a limit in normally transmitting/receiving large data. That is, in the current communication system, the signal field allocated to the data packet and bits allocated to check whether the signal field is normal or not are insufficient, which makes it impossible to stably transmit/receive large data at high speed through a limited resource.

Therefore, in order to stably transmit/receive large data at high speed through a limited resource in a communication system, for example, in the WLAN system, a method for accurately checking whether a signal field contained in a data packet is normal or not and normally transmitting/receiving data is required.

### SUMMARY OF THE INVENTION

An embodiment of the present invention is directed to a data transmission/reception apparatus and method in a communication system.

Another embodiment of the present invention is directed to a data transmission/reception apparatus and method for stably transmitting/receiving large data at high speed by accurately checking a signal field of a data packet transmitted/received through a limited resource in a communication system.

Another embodiment of the present invention is directed to a data transmission/reception apparatus and method which is capable of improving data throughput and a data error rate by accurately checking whether the signal field is normal or not through a plurality of bits of a signal field contained in a data packet in a communication system.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

In accordance with an embodiment of the present invention, a data transmission apparatus in a wireless communication system includes: a data field generation unit configured to generate a data field for transmitting data; a signal field generation unit configured to generate a signal field for transmitting information on the data field; and a transmission unit configured to transmit a data packet containing the data field and the signal field. The signal field includes a rate bit, a reservation bit, a length bit, a parity check bit, and a tail bit, and the data transmission apparatus transmits a check bit for checking whether the signal field is normal or not through two or more bits of the bits of the signal field.

In accordance with another embodiment of the present invention, a data reception apparatus in a wireless communication system includes: a reception unit configured to receive a data packet; a check unit configured to check whether a signal field contained in the data packet is normal or not; and a restoration unit configured to restore data received through a data field contained in the data packet according to whether the signal field is normal or not. The signal field includes a rate bit, a reservation bit, a length bit, a parity check bit, and a tail bit, and the check unit checks whether the signal field is normal or not by checking a check bit received through two or more bits of the bits of the signal field.

In accordance with another embodiment of the present invention, a data transmission method in a wireless communication system includes: generating a signal field for transmitting information on data transmission; generating a data field for the data transmission according to information contained in the signal field; and transmitting a data packet containing the data field and the signal field. The signal field includes a rate bit, a reservation bit, a length bit, a parity check bit, and a tail bit, and the data transmission apparatus transmits a check bit for checking whether the signal field is normal or not through two or more bits of the bits of the signal field.

In accordance with another embodiment of the present invention, a data reception method in a wireless communication system includes: receiving a data packet; checking whether a signal field contained in the data packet is normal or not; and restoring data received through a data field contained in the data packet according to whether the signal field is normal or not. The signal field includes a rate bit, a reservation bit, a length bit, a parity check bit, and a tail bit, and in said checking whether the signal field contained in the data packet is normal or not, whether the signal field is normal or not is checked by checking a check bit received through two or more bits of the bits of the signal field.

### BRIEF DESCRIPTION OF THE DRAWINGS

FIG. 1 schematically shows a signal field structure of a data packet in a communication system in accordance with an embodiment of the present invention.

FIGS. 2 to 6 schematically show a frame format of a data packet in the communication system in accordance with the embodiment of the present invention.

FIG. 7 schematically illustrates the structure of a data transmission apparatus in a communication system in accordance with an embodiment of the present invention.

FIG. 8 schematically illustrates the structure of a data reception apparatus in a communication system in accordance with another embodiment of the present invention.

FIG. 9 is a flow chart schematically showing the operation of the data transmission apparatus in the communication system in accordance with the embodiment of the present invention.

FIG. 10 is a flow chart schematically showing the operation of the data reception apparatus in the communication system in accordance with the embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

Exemplary embodiments of the present invention provide an apparatus and method for transmitting/receiving data in a communication system, for example, in a WLAN system. In the embodiments of the present invention, the WLAN system will be taken as an example in the following descriptions. However, the apparatus and method for transmitting/receiving data in accordance with the embodiments of the present invention may also be applied to other communication systems.

Furthermore, the exemplary embodiments of the present invention provide a method for stably transmitting/receiving large data, for example, a data packet at high speed through a limited resource, for example, a wireless channel in a communication system. Here, the data packet includes a data field containing data transmitted/received through the wireless channel and a signal field containing information on the data field. In the embodiments of the present invention, whether the signal field is normal or not is accurately checked, and the data contained in the data field are normally transmitted/received according to whether the signal field is normal or not. Therefore, large data are stably transmitted and received at high speed through a limited resource.

In the embodiments of the present invention, in order to stably transmit/receive large data at high speed through a limited resource, the large data are contained in the data field of the data packet and then transmitted/received as described above. For this operation, the data field of the data packet is expanded to the maximum, and the large data are transmitted/received through the data field. Furthermore, the signal field which is restrictively allocated depending on the data field is utilized as much as possible to contain information on the data field expanded to the maximum in the signal field, and the information is then normally transmitted/received.

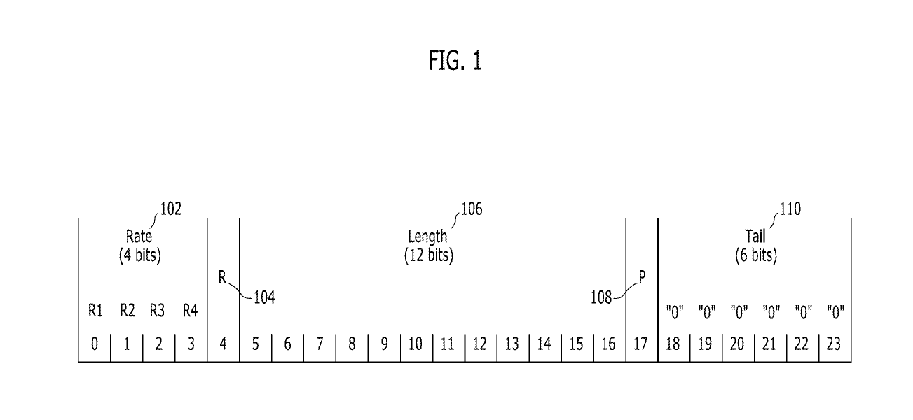

Furthermore, in the embodiments of the present invention, whether the signal field is normal or not is accurately checked through a plurality of bits of the signal field which is restrictively allocated depending on the data field, that is, whether the information on the data field, which is contained in the signal field, is normally transmitted/received or not is accurately checked to normally transmit/receive large data. As a result, a data throughput and data error rate may be improved, a malfunction of the system may be minimized, and large data may be stably transmitted/received at high speed through a limited resource. Now, referring to FIG. 1, a signal field of a data packet which a data transmission/reception apparatus in a communication system in accordance with an embodiment of the present invention transmits/receives through a limited resource will be described in detail.

FIG. 1 is a diagram schematically showing a signal field structure of a data packet in the communication system in accordance with the embodiment of the present invention.

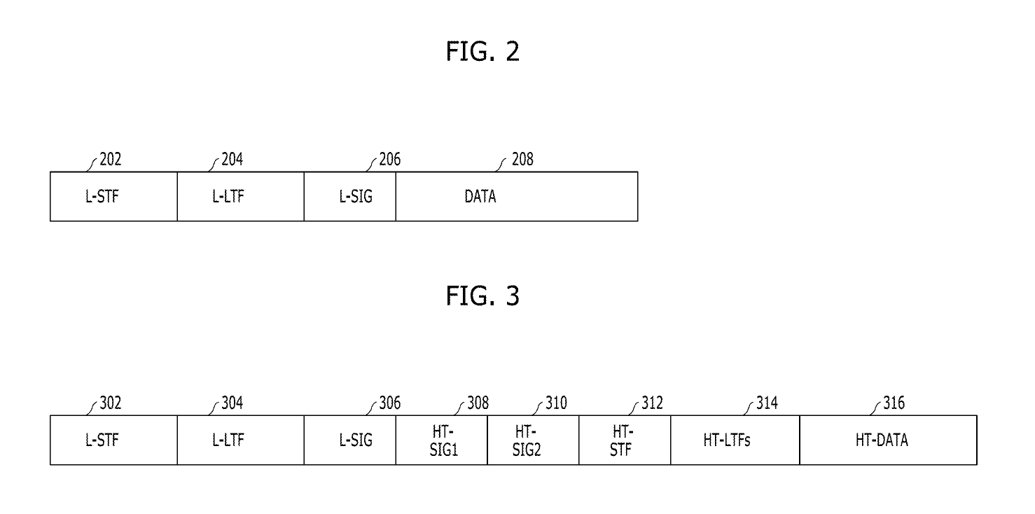

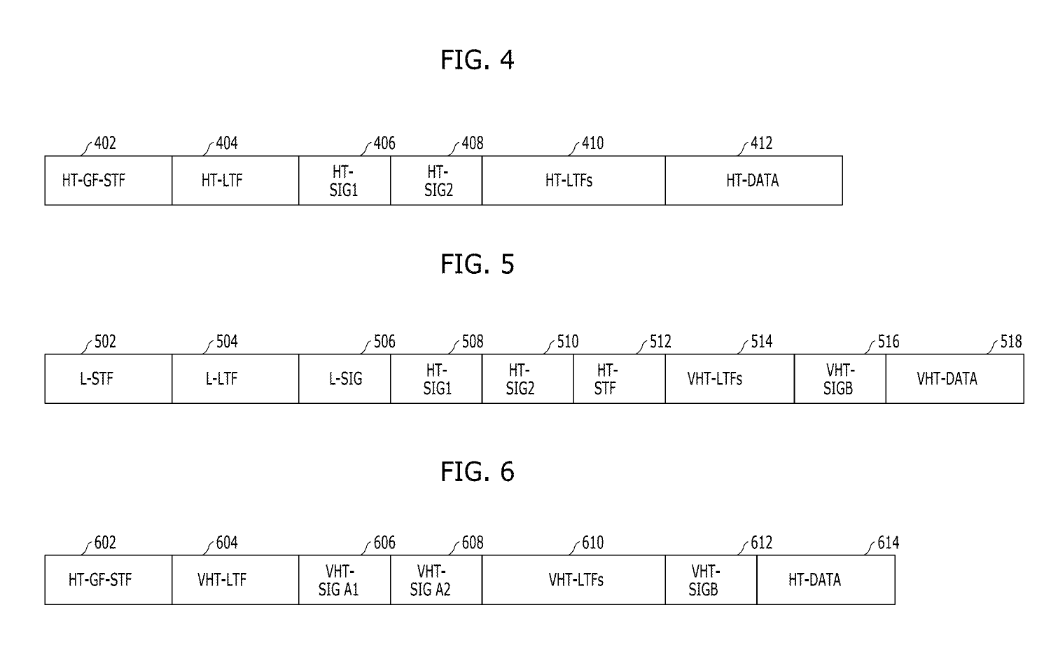

Referring to FIG. 1, the signal field contains information on a data field contained in a data packet as described above, and includes a rate bit 102, a reservation (R) bit 104, a length bit 106, a parity check (P) bit 108, and a tail bit 110, in order to contain the information on the data field. Referring to FIGS. 2 to 6, the frame of the data packet which is transmitted/received by the data transmission/reception apparatus in the communication system in accordance with the embodiment of the present invention will be described in more detail.

FIGS. 2 to 6 schematically show a frame format of a data packet in the communication system in accordance with the embodiment of the present invention.

Referring to FIGS. 2 to 6, the above-described data packet includes data fields for transmitting data and signal fields for transmitting information on the data field. In other words, the frame of the data packet includes data fields 208, 316, 412, 518, and 614, signal fields 206, 306, 308, 310, 406, 408, 506, 508, 510, 516, 606, 608, and 612, and training fields 202, 204, 302, 304, 312, 314, 402, 404, 410, 502, 504, 512, 514, 602, 604, and 610 for transmitting a preamble for the frame.

The data transmission/reception apparatus in the communication system in accordance with the embodiment of the present invention generates a signal field and a data field as described with reference to FIGS. 2 to 6, and then generates a frame of a data packet containing the signal field, the data field, and a training field as a preamble of the frame. Then, the data transmission/reception apparatus transmits/receives the generated frame of the data packet to thereby transmit/receive large data through a limited resource.

At this time, the data transmission/reception apparatus accurately checks whether the signal field is normal or not by using a plurality of bits of the signal fields, in order to normally transmit/receive data. In other words, the data transmission apparatus in the communication system in accordance with the embodiment of the present invention transmits a check bit which may be used to accurately check whether the signal field is normal or not, through the plurality of bits of the signal field, and the data reception apparatus accurately checks whether the signal field is normal or not by using the check bit transmitted through the plurality of bits of the signal field, and thus normally receives data to thereby improve data throughput and a data error rate. As a result, large data may be stably transmitted/received at high speed.

For example, the data transmission apparatus transmits a check bit for checking whether the signal field is normal or not, by using the plurality of bits of the signal field, for example, the rate bit 102, the reservation bit 104, the length bit 106, the parity check bit 108, and the tail bit 110 of the signal field, which have been described with reference to FIG. 1, when generating the signal field. Furthermore, the data reception apparatus accurately checks whether the signal field is normal or not, by using the check bit transmitted through the plurality of bits of the signal field, for example, the rate bit 102, the reservation bit 104, the length bit 106, the parity check bit 108, and the tail bit 110 of the signal field, which have been described with reference to FIG. 1, restores data contained in the data field according to whether the signal field is normal or not, and normally receives the data.

More specifically, the data transmission/reception apparatus transmits/receives a check bit for checking whether the signal field is normal or not, for example, a parity bit for parity check of the signal field or a cyclic redundancy check (CRC) bit for CRC of the signal field, by using the rate bit 102, the reservation bit 104, the length bit 106, the parity check bit 108, and the tail bit 110 of the signal field, which have been described with reference to FIG. 1.

For example, the data transmission apparatus transmits the parity bit through the rate bit 102 or the reservation bit 104 as well as the parity check bit 108 of the signal field, which has been described with reference to FIG. 1, that is, the parity bit check bit 108 and the rate bit 102, the parity bit check bit 108 and the reservation bit 104, or the parity bit check bit 108, the rate bit 102, and the reservation bit 104. The data transmission apparatus transmits the parity bit as a check bit for checking whether the signal field is normal or not, through at least one bit of the parity check bit 108, the rate bit 102, and the reservation bit 104. At this time, the transmission of the parity bit, that is, the check bit through the parity check bit 108, the rate bit 102, and the reservation bit 104 may be easily applied to another system, that is, may contribute to compatibility improvement.

Furthermore, the data transmission apparatus not only may transmit the parity bit through at least one bit of the parity check bit 108, the rate bit 102, and the reservation bit 104, but also may transmit the parity bit, that is, the check bit for checking whether the signal field is normal or not through the length bit 106. At this time, the data transmission apparatus transmits the parity bit through the least significant bit (LSB) of the length bit 106. Here, the data transmission apparatus transmits the parity bit, that is, the check bit through at least one bit of the parity check bit 108, the rate bit 102, and the reservation bit 104 as well as the LSB of the length bit 106.

The data transmission apparatus not only may transmit the parity bit through the parity check bit 108, the rate bit 102, the reservation bit 104, or the length bit 106, but also may transmit the parity bit, that is, the check bit for checking whether the signal field is normal or not through the tail bit 110. Here, the data transmission apparatus transmits the parity bit, that is, the check bit through at least one bit of the parity check bit 108, the rate bit 102, the reservation bit 104, and the length bit 106 as well as the tail bit 110.

For another example, the data transmission apparatus transmits the CRC bit through the rate bit 102 or the reservation bit 104 as well as the parity check bit 108 of the signal field, which has been described with reference to FIG. 1, that is, through the parity check bit 108 and the rate bit 102, the parity check bit 108 and the reservation bit 104, or the parity check bit 108, the rate bit 102, and the reservation bit 104. Here, the data transmission apparatus transmits the parity bit as the check bit for checking whether the signal field is normal or not, through at least one bit of the parity check bit 108, the rate bit 102, and the reservation bit 104. At this time, the transmission of the CRC bit, that is, the check bit through the parity check bit 108, the rate bit 102, and the reservation bit 104 may be easily applied to another system, that is, may contribute to compatibility improvement.

Furthermore, the data transmission apparatus not only may transmit the CRC bit through at least one bit of the parity check bit 108, the rate bit 102, and the reservation bit 104, but also may transmit the CRC bit, that is, the check bit for checking whether the signal field is normal or not through the length bit 106. At this time, the data transmission apparatus transmits the CRC bit through the LSB of the length bit 106. Here, the data transmission apparatus transmits the CRC bit, that is, the check bit through at least one of the parity check bit 108, the rate bit 102, and the reservation bit 104 as well as the LSB of the length bit 106.

The data transmission apparatus may not only transmit the CRC bit through the parity check bit 108, the rate bit 102, the reservation bit 104, or the length bit 106, but also may transmit the CRC bit, that is, the check bit for checking whether the signal field is normal or not through the tail bit 110. Here, the data transmission apparatus transmits the CRC bit, that is, the check bit through at least one bit of the parity check bit 108, the rate bit 102, the reservation bit 104, and the length bit 106 as well as the tail bit 110. At this time, as the data transmission apparatus transmits the CRC bit through the length bit 106 and the tail bit 110, the data transmission/reception performance in the system, that is, whether the signal field is normal or not may be accurately checked to thereby improve data throughput and an error rate.

The above descriptions have been focused on the case in which the data transmission apparatus transmits the parity bit or the CRC bit through the plurality of bits of the signal field, that is, transmits the parity bit and the CRC bit, respectively. However, the data transmission apparatus may simultaneously transmit the parity bit and the CRC bit through the plurality of bits of the signal field. For example, the data transmission apparatus may transmit the parity bit through the parity check bit 108, the rate bit 102, or the reservation bit 104 and transmit the CRC bit through the length bit 106 or the tail bit 110. That is, the data transmission apparatus in the communication system in accordance with the embodiment of the present invention transmits at least one check bit of the parity bit and the CRC bit through two or more of the rate bit 102, the reservation bit 104, the length bit 106, the parity check bit 108, and the tail bit 110 of the signal field shown in FIG. 1.

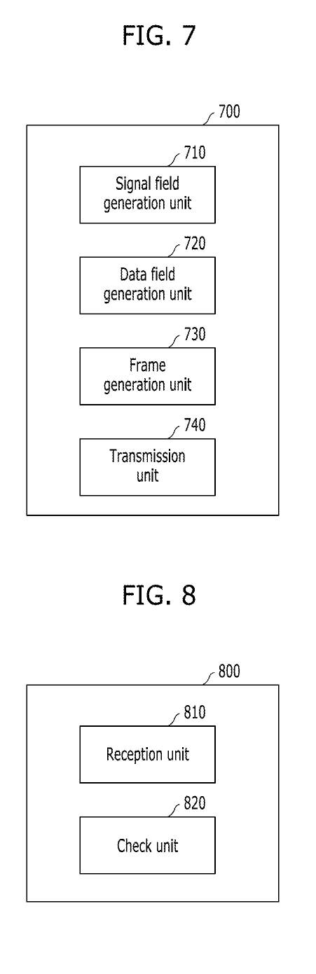

Furthermore, the data reception apparatus receives the data packet from the data transmission apparatus. At this time, the data reception apparatus checks the check bit transmitted through the plurality of bits of the signal field of the data packet as described above, for example, the parity bit or the CRC bit and accurately checks whether the signal field is normal or not. In other words, the data reception apparatus checks whether the signal field is normal or not through the parity check using the parity bit transmitted through the plurality of bits of the signal field or checks whether the signal field is normal or not through the CRC using the CRC bit transmitted through the plurality of bits of the signal field. Accordingly, the data reception apparatus accurately checks whether the signal field is normal or not, and normally receives data by restoring the data contained in the data field of the data packet according to whether the signal field is normal or not. At this time, as the data reception apparatus accurately checks whether the signal field is normal or not, a malfunction of the system may be minimized, and the data throughput and data error rate may be improved. Therefore, the data reception apparatus may stably receive large data at high speed. Then, referring to FIG. 7, the data transmission apparatus in the communication system in accordance with the embodiment of the present invention will be described in more detail.

FIG. 7 is a diagram schematically illustrating the structure of the data transmission apparatus in the communication system in accordance with the embodiment of the present invention.

Referring to FIG. 7, the data transmission apparatus includes a data field generation unit 720, a signal field generation unit 710, a frame generation unit 730, and a transmission unit 740, in order to transmit large data through a limited resource as described above. The data field generation unit 720 is configured to generate a data field for data transmission in a frame of a data packet. The signal field generation unit 730 is configured to generate a signal field for transmitting information on the data field. The frame generation unit 730 is configured to generate a training field for transmitting a preamble for the frame and generate the frame of the data packet containing the data field, the signal field, and the training field. The transmission unit 740 is configured to transmit the data packet to the data reception apparatus.

The signal field generation unit 710 generates the signal field as shown in FIG. 1. At this time, the signal field generation unit 710 contains a check bit in the plurality of bits of the signal field such that the check bit, for example, a parity bit or a CRC bit is transmitted through the plurality of bits of the signal field. The transmission unit 740 transmits the check bit to the data reception apparatus through the plurality of bits of the signal field. Here, the transmission of the check bit through the plurality of bits of the signal field has been already described above, and thus the detailed descriptions thereof are omitted herein. Then, referring to FIG. 8, the data reception apparatus in the communication system in accordance with the embodiment of the present invention will be described in detail.

FIG. 8 is a diagram schematically showing the structure of the data reception apparatus in the communication system in accordance with the embodiment of the present invention.

Referring to FIG. 8, the data reception apparatus includes a reception unit 810 configured to receive a data packet transmitted from the data transmission apparatus and a check unit 820 configured to check whether a signal field of the received data packet is normal or not.

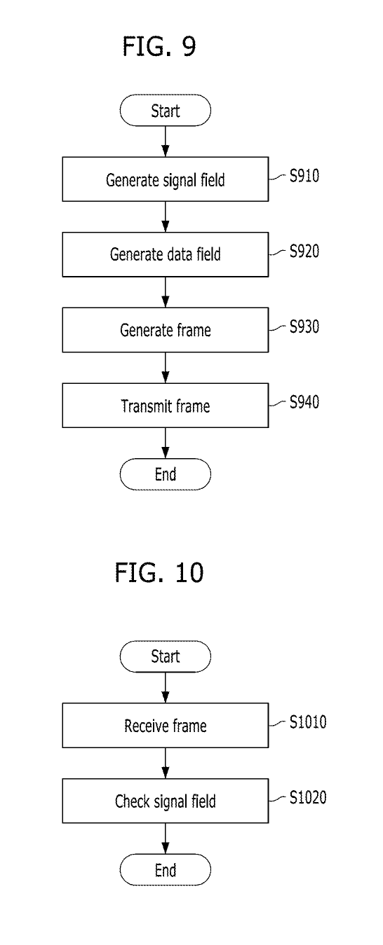

The reception unit 810 receives the data packet containing a data field, the signal field, and a training field as described above, and the check unit 820 checks whether the signal field is normal or not by using a check bit received through the plurality of bits of the signal field, for example, a parity bit or CRC bit. At this time, the check unit 820 checks whether the signal field is normal or not through the parity check using the parity bit or the CRC using the CRC bit, and a restoration unit (not illustrated) of the data reception unit normally receives data by restoring the data contained in the data field of the data packet according to whether the signal field is normal or not. Referring to FIG. 9, the data transmission of the data transmission apparatus in the communication system in accordance with the embodiment of the present invention will be described in more detail.

FIG. 9 is a flow chart schematically showing the operation of the data transmission apparatus in the communication system in accordance with the embodiment of the present invention.

Referring to FIG. 9, the data transmission apparatus generates a signal field containing information on data transmission, in order to transmit large data through a limited resource as described above, at step S910. Here, a plurality of bits of the signal field include a check bit for checking whether the signal field is normal or not, for example, a parity bit or CRC bit.

At step S920, the data transmission apparatus generates a data field for data transmission according to the information on data transmission which is contained in the signal field. At step S930, the data transmission apparatus generates a training field for preamble transmission and generates a frame of the data packet containing the data field, the signal field, and the training field.

At step S940, the data transmission apparatus transmits a data packet by transmitting the frame to the data reception apparatus. At this time, in order to check whether the signal field of the data packet is normal or not, the data transmission apparatus transmits the check bit through the plurality of bits of the signal field. Here, the transmission of the check bit through the plurality of bits of the signal field has been already described above, and the detailed descriptions thereof are omitted herein. Then, referring to FIG. 10, the data reception of the data reception apparatus in the communication system in accordance with the embodiment of the present invention will be described in more detail.

FIG. 10 is a flow chart schematically showing the operation of the data reception apparatus in the communication system in accordance with the embodiment of the present invention.

Referring to FIG. 10, the data reception apparatus receives the frame of the data packet transmitted from the data transmission apparatus at step S1010, and the data reception apparatus checks whether the signal field of the received data packet is normal or not, at step S1020. Here, the data reception apparatus checks whether the signal field is normal or not by using the check bit received through the plurality of bits of the signal field of the received data packet, for example, the parity bit or CRC bit. At this time, the data reception apparatus checks whether the signal field is normal or not through the parity check using the parity bit or the CRC using the CRC bit. Furthermore, the data reception apparatus normally receives the data by restoring the data contained in the data field of the data packet according to whether the signal field is normal or not.

In accordance with the embodiments of the present invention, whether the signal field is normal or not is accurately checked through the plurality of bits of the signal field contained in the data packet transmitted/received through a limited resource in the communication system, and thus the data throughput and the error rate may be improved. Furthermore, large data may be stably transmitted/received at high speed through the limited resource. In particular, the signal field having a limited size may be utilized as much as possible to accurately check whether the information on the data field of the data packet is normally transmitted/received or not and whether the transmission/reception is normally performed or not. Therefore, large data may be normally transmitted/received to improve the data throughput and the data error rate, and a malfunction of the system may be minimized.

While the present invention has been described with respect to the specific embodiments, it will be apparent to those skilled in the art that various changes and modifications may be made without departing from the spirit and scope of the invention as defined in the following claims.

What is claimed is:

1. A data transmission apparatus in a wireless communication system, comprising:
a data field generation unit configured to generate a data field for transmitting data;
a signal field generation unit configured to generate a signal field for transmitting information on the data field; and
a transmission unit configured to transmit a data packet containing the data field and the signal field,
wherein the signal field comprises a rate bit, a reservation bit, a length bit, a parity check bit, and a tail bit, and
the data transmission apparatus transmits a check bit for checking whether the signal field is normal or not through two or more bits of the bits of the signal field.

2. The data transmission apparatus of claim 1, wherein the check bit comprises at least one of a parity bit for parity check of the signal field and a cyclic redundancy check (CRC) bit for CRC of the signal field.

3. The data transmission apparatus of claim 2, wherein the parity bit is transmitted through the rate bit, the reservation bit, the parity check bit.

4. The data transmission apparatus of claim 2, wherein the CRC bit is transmitted through the length bit and the tail bit.

5. A data reception apparatus in a wireless communication system, comprising:
a reception unit configured to receive a data packet;
a check unit configured to check whether a signal field contained in the data packet is normal or not; and
a restoration unit configured to restore data received through a data field contained in the data packet according to whether the signal field is normal or not,
wherein the signal field comprises a rate bit, a reservation bit, a length bit, a parity check bit, and a tail bit, and
the check unit checks whether the signal field is normal or not by checking a check bit received through two or more bits of the bits of the signal field.

6. The data reception apparatus of claim 5, wherein the check bit comprises at least one of a parity bit for parity check of the signal field and a CRC bit for CRC of the signal field.

7. The data reception apparatus of claim 6, wherein the check unit performs the parity check of the signal field by using the parity bit received through the rate bit, the reservation bit, and the parity check bit.

8. The data reception apparatus of claim 6, wherein the check unit performs the CRC of the signal field by using the CRC bit received through the length bit and the tail bit.

9. A data transmission method in a wireless communication system, comprising:
generating a signal field for transmitting information on data transmission;
generating a data field for the data transmission according to information contained in the signal field; and
transmitting a data packet containing the data field and the signal field,
wherein the signal field comprises a rate bit, a reservation bit, a length bit, a parity check bit, and a tail bit, and
the data transmission apparatus transmits a check bit for checking whether the signal field is normal or not through two or more bits of the bits of the signal field.

10. The data transmission method of claim 9, wherein the check bit comprises at least one of a parity bit for parity check of the signal field and a CRC bit for CRC of the signal field.

11. The data transmission method of claim 10, wherein the parity bit is transmitted through the rate bit, the reservation bit, the parity check bit.

12. The data transmission method of claim 10, wherein the CRC bit is transmitted through the length bit and the tail bit.

13. A data reception method in a wireless communication system, comprising:
receiving a data packet;
checking whether a signal field contained in the data packet is normal or not; and
restoring data received through a data field contained in the data packet according to whether the signal field is normal or not,
wherein the signal field comprises a rate bit, a reservation bit, a length bit, a parity check bit, and a tail bit, and
in said checking whether the signal field contained in the data packet is normal or not, whether the signal field is normal or not is checked by checking a check bit received through two or more bits of the bits of the signal field.

14. The data reception method of claim 13, wherein the check bit comprises a parity bit for parity check of the signal field and a CRC bit for CRC of the signal field.

15. The data reception method of claim 14, wherein, in said checking whether the signal field contained in the data packet is normal or not, the parity check of the signal field is performed by using the parity bit received through the rate bit, the reservation bit, and the parity check bit.

16. The data reception method of claim 14, wherein, in said checking whether the signal field contained in the data packet is normal or not, the CRC of the signal field is performed by using the CRC bit received through the length bit and the tail bit.
